(19) United States
(12) Patent Application Publication
(10) Pub. No.: US 2004/0097027 A1
(43) Pub. Date: May 20, 2004

(54) Method for manufacturing semiconductor device

(76) Inventor: Won-Kyu Park, Daegu Metropolitan City (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/712,716

(22) Filed: Nov. 13, 2003

(30) Foreign Application Priority Data
Nov. 14, 2002 (KR) 2002-70858
Nov. 14, 2002 (KR) 2002-70857

(51) Int. Cl. H01L 21/336; H01L 21/8234; H01L 21/8242

(52) U.S. Cl. 438/197; 438/301; 438/305; 438/250

(57) ABSTRACT

The present invention relates to a method for manufacturing a semiconductor device, and more particularly, to a method for manufacturing a semiconductor device, in which a LDD region is formed by implanting phosphor or as impurities, then a high concentration As is implanted to a bit line contact region and a gate poly and then phosphor is implanted again to the bit line contact region and the gate poly, so that the high concentration As can be surrounded by the phosphor implanted two times, whereby the resistance of the bit line contact and a data path can be maintained low and the leakage current and junction capacitance caused by the high implanting concentration of As of the bit line contact junction can be drastically lowered, thus improving the characteristics of a DRAM, and whereby the space between a MOS capacitor and a gate is reduced to minimize the generation of the Tr-off current and the capacitor region can be increased to increase the capacitance of the device.

### BACKGROUND

1. Technical Field

The present invention relates to a method for manufacturing a semiconductor device, and more particularly, to a method for manufacturing a semiconductor device, in which a LDD region is formed by implanting phosphor or as an impurity, then a high concentration As is implanted to a bit line contact region and a gate poly and then phosphor is implanted again to the bit line contact region and the gate poly, so that the high concentration As can be surrounded by the phosphor implanted two times, whereby the resistance of the bit line contact and a data path can be maintained low and the leakage current and junction capacitance caused by the high implanting concentration of As of the bit line contact junction can be drastically lowered, thus improving the characteristics of a DRAM, whereby the space between a MOS capacitor and a gate is reduced to minimize generation of the Tr-off current and the capacitor region can be increased to increase the capacitance of the device.

2. Description of the Related Art

In a MOS capacitor DRAM developed for the integration with logic, a data storage portion and a path for the data is comprised of junctions. However, if the MOS capacitor DRAM is manufactured by a conventional manufacturing method, in order to acquire a high electric current of the transistor, the dose of as used, as an impurity is kept high. Accordingly, a junction having a high as concentration is formed on a bit line contact portion or between a capacitor and a gate electrode. Due to such a high concentration of as contained in the junction, there is a problem in that the leakage current becomes higher.

Particularly, as the concentration of As contained in the junction serving as a data path between the capacitor and the gate electrode in the MOS capacitor DRAM, the capacitor and the junction serving as the data path are electrically connected even in the off state of the device and thus current flows. Due to such a high Tr-off current, there may be a problem in that the refresh characteristics of the device deteriorate.

Hereinafter, the problems shown in the conventional method for manufacturing a semiconductor device will be described in more detail with reference to the accompanying drawings.

FIGS. 1a to 1i are flow charts showing a method for manufacturing a MOS capacitor DRAM in the conventional art.

According to the conventional method for manufacturing the MOS capacitor DRAM, firstly, as shown in FIG. 1a, a device isolation film is formed by a STI (Shallow Trench Isolation) process, and then a p-well 2 for the formation of a MOS capacitor and a transistor is formed. Thereafter, as shown in FIG. 1b, a gate oxide film 3 is grown on the top of a semiconductor substrate with the device isolation film 1 and the p-well 2, and a gate poly 4 is deposited on top of the gate oxide film 3.

Afterwards, as shown in FIG. 1c, with respect to the resulting material obtained by depositing the gate poly 4, a photoetching process using photoresist is carried out to form a photoresist pattern 5 so that a gate electrode region and a MOS capacitor region of the transistor can be defined. Then, using the photoresist pattern 5, a dry etching process is carried out to form the gate electrode and MOS capacitor of the transistor. On the space between the gate electrode and the MOS capacitor, a junction serving as a data path in the final device is formed. In the further steps, in order to lower the resistance of the data path, a process of implanting As of a high concentration as impurities and forming titanium silicide. For the convenience of this process, the space between the gate electrode and the MOS capacitor is defined as about 0.42 μm.

After carrying out the process of defining the capacitor region, as shown in FIG. 1d, an oxidation process is carried out to the gate poly, to thus grow an oxide film 6 on top of the gate poly. To increase the current of a finally formed transistor, As is implanted as an impurity to the silicon substrate between the gate electrode and the capacitor or between the gate electrodes, to thus form a LDD region 7. At this time, in order to increase the current of the transistor, the concentration of As implanted as impurities is maintained high. Due to this, the capacitor and the junction region implanted with as an impurity are electrically connected even in the off state of the transistor, thus a current flows. And, due to the generation of such a Tr-off current, the refresh characteristics of the device are deteriorated. Moreover, since the concentration of As implanted as impurities is high, a high leakage current is generated, and the capacitance of a bit line contact junction between the gate electrodes implanted with As becomes higher. Thus, due to the leakage current and the high capacitance of the junction, the characteristics of the device can be deteriorated.

After carrying out the process of implanting impurities, as shown in FIG. 1e, a HLD oxide film is deposited on the side walls of the gate electrode and of the capacitor at a thickness of 1900 Å. By carrying out spacer etching through a dry etching process, a spacer 8 is formed on the sidewalls of the gate electrode and of the capacitor. Thereafter, as shown in FIG. 1f, As of a high concentration is implanted as impurities to the entire surface of the resulting material with the spacer 8. Accordingly, the gate poly 10 defining the capacitor and the gate electrode, a bitline contact portion between the gate electrodes and an active portion between the capacitor and the gate electrode are doped.

That is to say, in the above process, as, of a high concentration is implanted one more time to the entire surface of the resulting material with the spacer 8. Due to this second process of implanting impurities, the concentration of As implanted to each of the junction portions becomes much higher, and thus the capacitance of the bit line contact junction become much higher and the leakage current and the Tr-off current also becomes much higher.

Next, as shown in FIG. 1g, a high temperature RAP (Rapid Thermal Process) process is adapted to the doped material to activate it, and then titanium 11 is deposited to the entire surface of the activated resulting material. The titanium 11 is supposed to form a titanium silicide in a further process. At this time, by the above as implanting process, junctions 9 are formed on the bit line contact portion between the gate electrodes and on the space between the capacitor and the gate electrode. Due to a high as concentration of the junction portions, the capacitance of the junctions becomes higher and the leakage current also becomes higher.

After the deposit of the titanium 11, as shown in FIG. 1h, one more RTP process is adapted to the resulting material deposited with the titanium 11, thereby growing a titanium silicide 12 on the gate poly, the bitline contact junction region and the junction between the capacitor and the gate electrode except the region having the spacer 8 oxide film. Afterwards, as shown in FIG. 1i, an interlayer insulating film 13 is formed, a bit line contact and a bit line 14 are formed, and a bias contact of the MOS capacitor is formed, thereby finally forming a MOS capacitor DRAM.

In other words, according to the conventional method for manufacturing the semiconductor device, as shown in FIG. 1i, As of a high concentration is implanted to the junction 15 region serving as a data path between the capacitor and the gate electrode. Thusly, due to the as of the high concentration, the capacitor and the junction are electrically connected even in the off state of the transistor, to thus generate a high Tr-off current. In addition, the capacitance of the bit line contact junction region between the gate electrodes becomes higher, thus a sensing voltage becomes lower and the resultant characteristics of the device are deteriorated.

In conclusion, the conventional method for manufacturing the semiconductor device was problematic in that a relatively high leakage current and a high capacitance of the junction are generated due to a high As concentration of each of the junction regions, thereby deteriorating the refreshing characteristics of the device.

### SUMMARY OF THE DISCLOSURE

The present invention is designed in consideration of the problems of the prior art, and therefore it is an object of the present invention to provide a method for manufacturing a semiconductor device, by which the resistance of the bit line contact and a data path can be maintained low and the leakage current and junction capacitance caused by the high implanting concentration of As of the bit line contact junction can be drastically lowered, thus improving the characteristics of a DRAM, and whereby the space between a MOS capacitor and a gate is reduced to minimize the generation of the Tr-off current and the capacitor region can be increased to increase the capacitance of the device.

To achieve the above object, there is provided a method for manufacturing a semiconductor device, comprising the steps of: defining gate electrode and capacitor regions by adapting a photoetching process to a semiconductor substrate deposited with a gate oxide film and a gate poly, so that the distance between the gate electrode region and the capacitor region can be smaller than twice the thickness of a spacer to be formed later; growing an oxide film on top of the gate poly and defining a LDD region using phosphor as impurities; forming a spacer by depositing and etching an oxide film on the sidewalls of the gate oxide film and gate poly where the gate electrode and capacitor regions are defined; implanting a high concentration of As on the surface of a bit line contact junction and a gate poly formed between the gate electrodes by implanting a high concentration As to the surface of the resulting material with the spacer; and implanting phosphor (P) as impurities so as to surround the region implanted with As.

In other words, in the present invention, since the distance between the gate electrode and the capacitor is smaller than twice the thickness of a spacer to be formed later, when an oxide film is deposited onto the sidewalls of the gate electrode and of the capacitor later, the space between the gate electrode and the capacitor is completely filled with the oxide film. Thus, even if a process of implanting As of high concentration is carried out, it is possible not to have As implanted between the gate electrode and the capacitor, thereby minimizing the problem of the Tr-off current generated due to a high concentration As. Further, the As implanted to the bit line contact junction portion is surrounded by the phosphor implanted two times, thus the junction capacitance and leakage current caused by the high concentration of As can be minimized.

In the method for manufacturing the semiconductor device of the present invention, the step of defining the LDD region is carried out by implanting phosphor with a concentration of 5×10¹³ atoms/cm² at a depth of about 200 Å, and the step of implanting phosphor as impurities so as to surround the region implanted with As is carried out by implanting phosphor with a concentration of 5×10¹³ atoms/cm² at a depth of about 600 Å. Thus, the high concentration of As implanted at a depth of about 400 Å is surrounded by the phosphor implanted two times, thereby minimizing the leakage current and junction capacitance caused by the high concentration As.

Further, in the method for manufacturing of the semiconductor device of the present invention, the distance between the gate electrode region and the capacitor region is preferably smaller than 0.26 μm. By defining the gate electrode and capacitor regions by this distance, the space between the capacitor and the gate electrode can be completely buried with the oxide film. Thusly, even if a process of implanting As of a high concentration is carried out, it is possible not to have as implanted between the gate electrode and the capacitor, thereby minimizing the problem of the Tr-off current generated due to a high concentration.

### BRIEF DESCRIPTION OF THE DRAWINGS

Other objects and aspects of the present invention will become apparent from the following description of embodiments with reference to the accompanying drawing in which:

FIGS. 1a to 1i are flow charts showing a conventional method for manufacturing a MOS capacitor DRAM;

FIGS. 2a to 2h are views showing a process sequence of a method for manufacturing a semiconductor device according to one embodiment of the present invention; and

FIGS. 3a to 3h are views showing a process sequence of a method for manufacturing a semiconductor device according to another embodiment of the present invention.

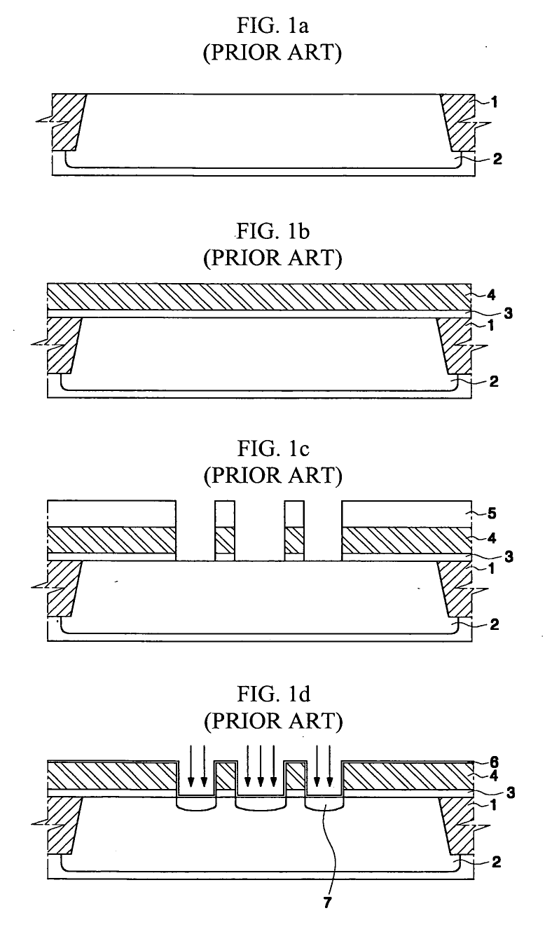

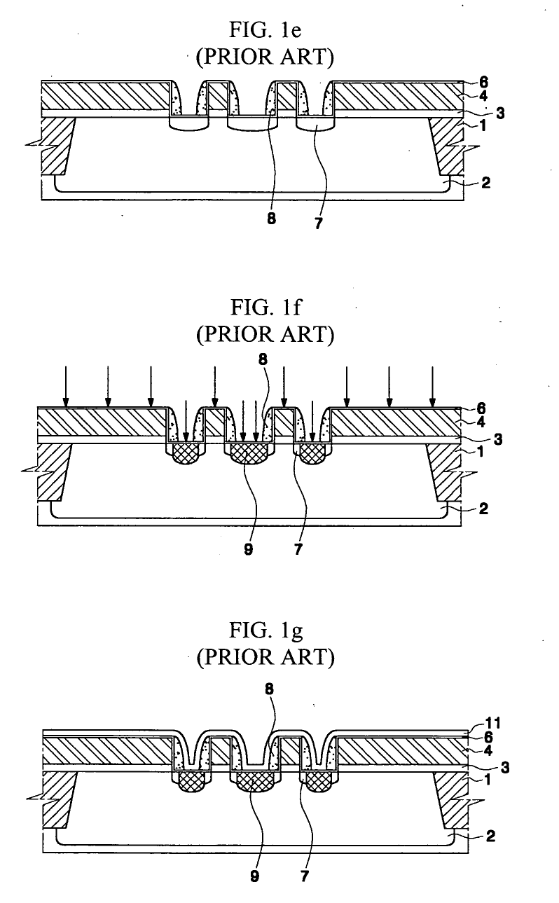

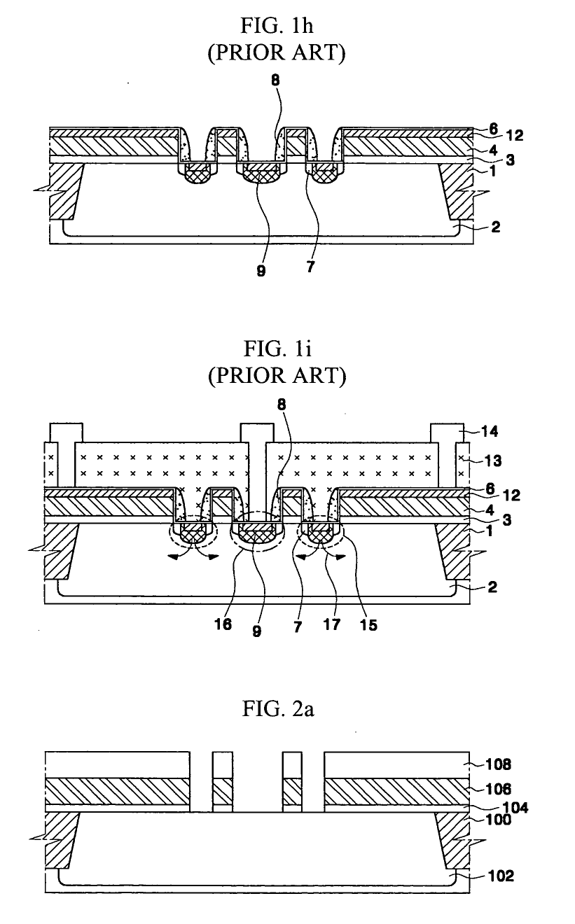

### DETAILED DESCRIPTION OF THE PRESENTLY PREFERRED EMBODIMENT

Hereinafter, a preferred embodiment of the present invention will be described in more detail referring to the drawings. In addition, the following embodiment is just for illustration only, not intended to limit the scope of the invention.

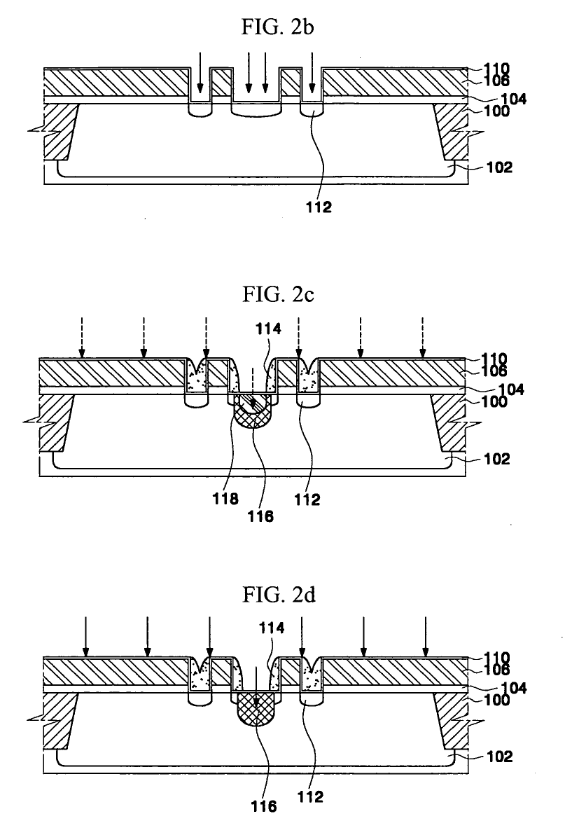

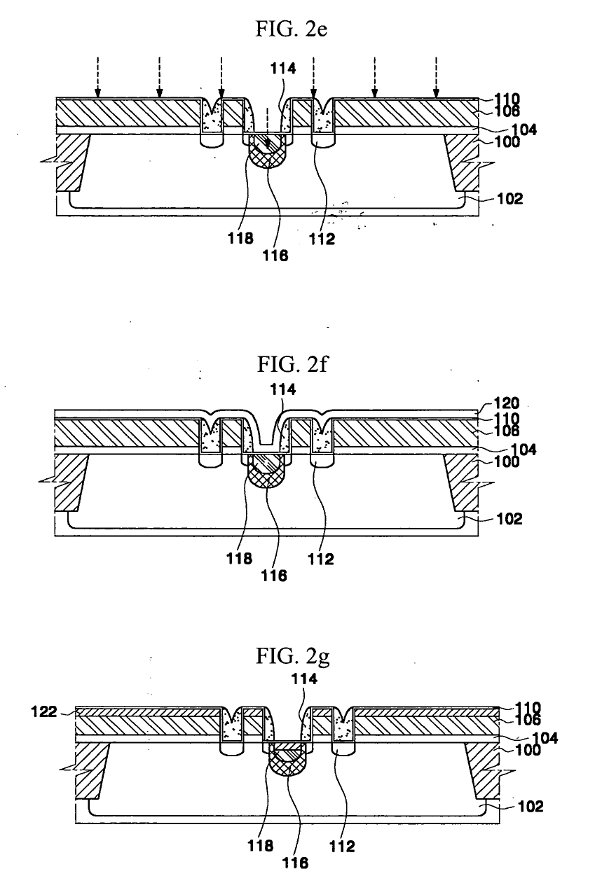

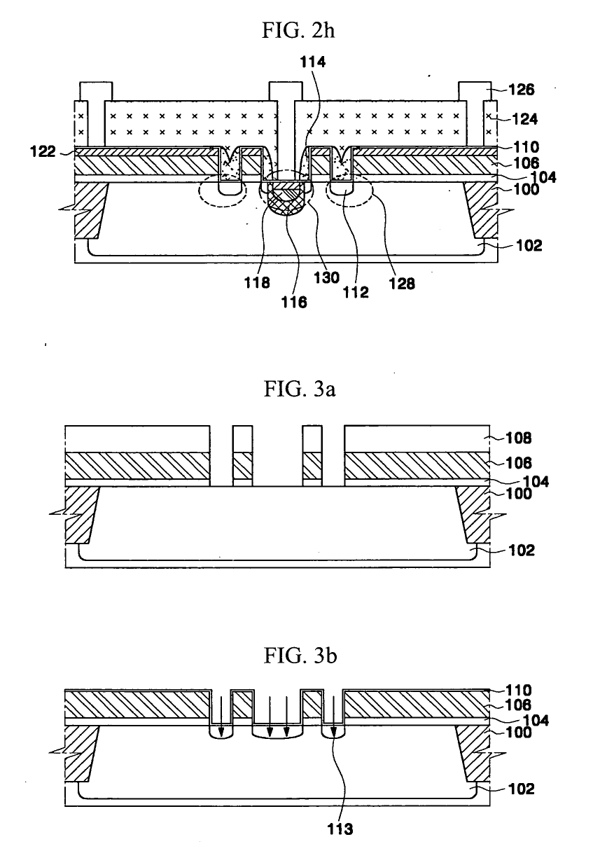

FIGS. 2a to 2h are views showing a process sequence of a method for manufacturing a semiconductor device according to one embodiment of the present invention.

According to the manufacturing method according to the present invention, firstly, as in the conventional method, a device isolation film 100, a p-well 102, a gate oxide film 104 and a gate poly 106 are sequentially formed. Then, as shown in FIG. 2a, with respect to the resulting material deposited with the gate poly 106, a photoetching process using a photoresist is carried out to form a photoresist pattern 108 so that gate electrode and MOS capacitor regions of a transistor can be defined. Then, a dry etching process is carried out on the photoresist pattern 108 using an etching mask to form a gate electrode and a MOS capacitor. At this time, the distance between the gate electrode and the MOS capacitor is smaller than twice the thickness of a spacer to be formed later, which corresponds to the smallest distance that can be implemented in the photoetching and dry etching, for example, 0.26 μm.

In other words, in the above process, by making the distance between the gate electrode and the capacitor smaller than twice the thickness of a spacer to be formed later, when an oxide film is deposited to the sidewalls of the gate electrode and of the capacitor later, the space between the gate electrode and the capacitor is completely buried with the oxide film. Thus, even if a process of implanting As of a high concentration is carried out, it is possible not to have As implanted between the gate electrode and the capacitor.

After the formation of the gate electrode and the capacitor, as shown in FIG. 2b, an oxidation process is carried out to the gate poly 106, thereby growing an oxide film 110 on top of the gate poly 106. To increase the current of a final transistor, phosphor with a concentration of 5×10¹³ atoms/cm² is implanted as impurities on the silicon substrate between the gate electrode and the capacitor and between the gate electrodes at a depth of about 200 Å, to thus form a LDD region 112. Because phosphor has high dispersion characteristics with respect to a successive thermal process, the generation of a transistor punch can be inhibited by implanting phosphor at a low energy level of 15 KeV. At this time, due to the high dispersion, the implantation depth of phosphor becomes large and thus the surface resistance of the data path becomes lower. Moreover, due to the low concentration of phosphor, the capacitance of the junction region can be lowered. Thus, the parasitic capacitance components in the capacitor are reduced and thus the voltage-dependant characteristics can be improved.

After carrying out the process of forming the LDD region 112, as shown in FIG. 2c, a HLD oxide film is deposited on the sidewalls of the gate electrode and of the capacitor at a thickness of 1900 Å. Then, by carrying out spacer etching through a dry etching process, a spacer 114 is formed on the sidewalls of the gate electrode and of the capacitor. By this process, as described above, the space between the gate electrode and the capacitor defined as 0.26 μm is buried with the HLD oxide film. Accordingly, even if the process of implanting As of a high concentration is carried out later, the space between the gate electrode and the capacitor is not affected by such the implanting process. For this reason, the Tr-off current generated in the conventional art due to a high As concentration between the gate electrode and the capacitor can be minimized.

After carrying out the process of forming the spacer 114, as shown in FIG. 2d, As of a high concentration is implanted as impurities on the entire surface of the resulting material with the spacer 114 at a depth of about 400 Å. Accordingly, it is possible to dope the gate poly 106 and the bit line contact portion 116 between the gate electrodes defining the capacitor and the gate electrode.

Next, as shown in FIG. 2e, phosphor with a concentration of 5×10¹³ atoms/cm² is implanted at a depth of about 600 Å so as to surround the region implanted with As. As a result, As of a high concentration is implanted to the portion 118 wherein titanium silicide to be formed later and a contact point are made in the bit line contact junction region between the gate electrodes. Such the region implanted with As is surrounded by the phosphor implanted two times. Therefore, the leakage current caused by the high concentration As can be eliminated. In addition, because an interface caused by the phosphor doped at a low concentration is formed on the boundary surface of the junction region, thus the capacitance of the junction also becomes drastically lowered. Moreover, according to the present invention, the region between the capacitor and the gate electrode is completely buried with the oxide film, thus a high concentration As cannot penetrate into the region, and the Tr-off current and the leakage current can be minimized.

After carrying out the process of implanting phosphor, as shown in FIG. 2f, a high temperature RTP (Rapid Thermal Process) process is adapted to the doped resulting material to activate it, and then titanium 120 is deposited to the entire surface of the activated resulting material. The titanium 120 is supposed to form a titanium silicide in a further process. Thereafter, as shown in FIG. 2g, one more RTP process is adapted to the resulting material deposited with the titanium 120, thereby growing a titanium silicide 122 on the gate poly 106 and the bit line contact junction region 118 except the region having the spacer 114 oxide film. Afterwards, as shown in FIG. 2h, an interlayer insulating film 124 is formed, a bit line contact and a bit line 126 are formed, and a bias contact of the MOS capacitor is formed, thereby finally forming a MOS capacitor DRAM.

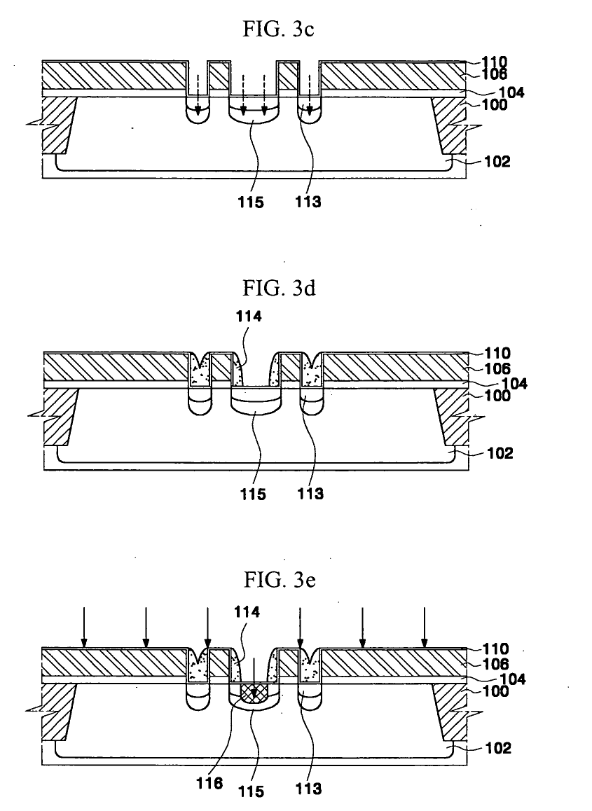

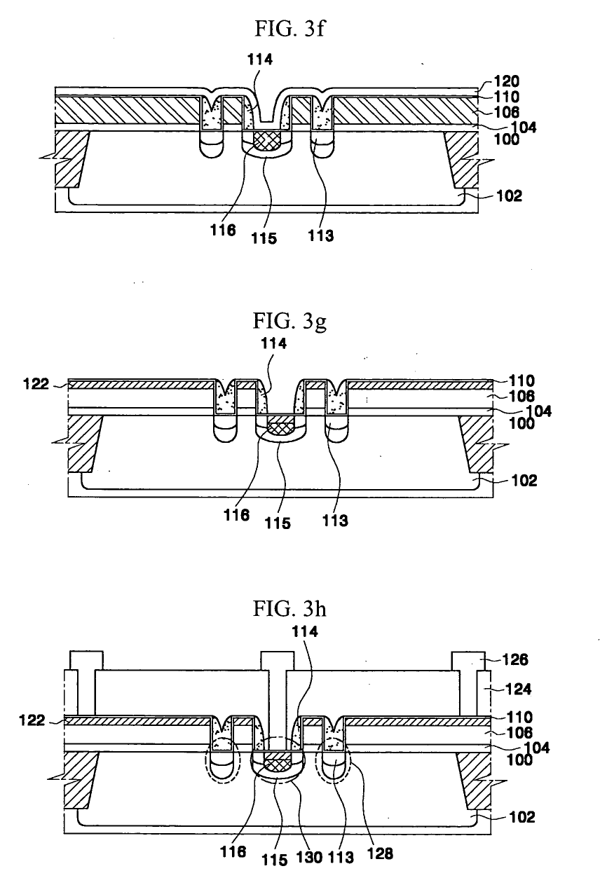

FIGS. 3a to 3h are views showing a process sequence of a method for manufacturing a semiconductor device according to another embodiment of the present invention. With respect to the same configuration, the same reference numerals are used.

Firstly, as in the conventional method, a device isolation film 100, a p-well 102, a gate oxide film 104 and a gate poly 106 are sequentially formed. Then, as shown in FIG. 3a, with respect to the resulting material deposited with the gate poly 106, a photoetching process using a photoresist is carried out to form a photoresist pattern 108 so that gate electrode and MOS capacitor regions of a transistor can be defined. Then, a dry etching process is carried out to the photoresist pattern 108 using an etching mask to form a gate electrode and a MOS capacitor. At this time, the distance between the gate electrode and the MOS capacitor is smaller than twice the thickness of a spacer to be formed later, which corresponds to the smallest distance that can be implemented in the photoetching and dry etching, for example, 0.26 μm.

In other words, in the above process, by making the distance between the gate electrode and the capacitor smaller than twice the thickness of a spacer to be formed later, when an oxide film is deposited to the sidewalls of the gate electrode and of the capacitor later, the space between the gate electrode and the capacitor is completely buried with the oxide film. Thus, even if a process of implanting As of a high concentration is carried out, it is possible not to have as implanted between the gate electrode and the capacitor.

After the formation of the gate electrode and the capacitor, as shown in FIG. 3b, an oxidation process is carried out to the gate poly 106, thereby growing an oxide film 110 on top of the gate poly 106. To increase the current of a final transistor, As is implanted as an impurity on the silicon substrate between the gate electrode and the capacitor and between the gate electrodes at a depth of about 200 Å, to thus form a first LDD region 113.

Then, as shown in FIG. 3c, phosphor (P) is implanted as impurities at t depth of about 500 Å so as to surround the first LDD region 113, thereby forming a second LDD region 115. In the present invention, by carrying out this step, a thick, double LDD layer is formed on the region between the capacitor and the gate electrode and on the region between the gate electrodes. Since the second LDD region 115 surrounds the first LDD region 113, this can prevent the generation of a leakage current caused by a high concentration of As. Further, a light doping junction interface is formed between the first LDD region 113 and the second LDD region 115, thereby reducing the leakage current generated in the junction by one-tenth.

After carrying out the process of forming the second LDD region 115, as shown in FIG. 3d, a HLD oxide film is deposited on the sidewalls of the gate electrode and of the capacitor at a thickness of 1900 Å. Then, by carrying out spacer etching through a dry etching process, a spacer 114 is formed on the sidewalls of the gate electrode and of the capacitor. By this process, the space between the gate electrode and the capacitor defined as 0.26 μm is buried within the HLD oxide film. Accordingly, even if the process of implanting As of a high concentration is carried out later, the space between the gate electrode and the capacitor is not affected by such a process. For this reason, the Tr-off current generated in the conventional art due to a high As concentration between the gate electrode and the capacitor can be minimized.

After carrying out the process of forming the spacer 114, as shown in FIG. 3e, As of a high concentration is implanted as impurities on the entire surface of the resulting material with the spacer 114. Accordingly, it is possible to dope the gate poly 106 and the bit line contact portion 116 between the gate electrodes defining the capacitor and the gate electrode. However, in the manufacturing method of the present invention, since As implanted to the bit line contact portion 116 exists in the second LDD region 115, the leakage current caused by the high concentration As contained in the bit line contact junction portion can be eliminated, and at the same time the capacitance of the junction portion can be drastically lowered. Moreover, the space between the gate electrode and the capacitor is completely buried with the oxide film as described above, thus the high concentration As cannot be penetrated to the space, thereby minimizing the generation of the leakage current and Tr-off current.

After carrying out the process of implanting a high concentration as shown in FIG. 3f, a high temperature RTP (Rapid Thermal Process) process is adapted to the doped resulting material to activate it, and then titanium 120 is deposited to the entire surface of the activated resulting material. The titanium 120 is supposed to form a titanium silicide in a further process. Thereafter, as shown in FIG. 3g, one more RTP process is adapted to the resulting material deposited with the titanium 120, thereby growing a titanium silicide 122 on the gate poly 106 and the bit line contact portion 116 excepting the region having the spacer 114 oxide film. Afterwards, as shown in FIG. 3h, an interlayer insulating film 124 is formed, a bit line contact and a bit line 126 are formed, and a bias contact of the MOS capacitor is formed, thereby finally forming a MOS capacitor DRAM.

Therefore, according to the method for manufacturing the semiconductor device according to the present invention, the resistance of a bit line contact and a data path can be maintained at a low level, the leakage current and junction capacitance caused by a high concentration As can be minimized, and the Tr-off current between the gate electrode and the capacitor can be minimized.

Accordingly, according to the manufacturing method of the present invention, the characteristics of a final DRAM can be drastically improved. Further, the minimizing of the space between the gate electrode and the capacitor can increase the capacitor region, thereby increasing the capacitance of the device.

What is claimed is:

1. A method for manufacturing a semiconductor device, comprising the steps of:
defining gate electrode and capacitor regions by adapting a photoetching process to a semiconductor substrate deposited with a gate oxide film and a gate poly, so that the distance between the gate electrode region and the capacitor region can be smaller than twice the thickness of a spacer to be formed later;
growing an oxide film on top of the gate poly and defining a LDD region using phosphor (P) as impurities;
forming a spacer by depositing and etching an oxide film on the sidewalls of the gate oxide film and gate poly where the gate electrode and capacitor regions are defined;
implanting a high concentration As on the surfaces of a bit line contact junction and a gate poly formed between the gate electrodes by implanting a high concentration As to the surface of the resulting material with the spacer; and
implanting phosphor (P) as impurities so as to surround the region implanted with As.

2. The method of claim 1, wherein the step of defining the LDD region is carried out by implanting phosphor with a concentration of 5×10¹³ atoms/cm² at a depth of about 200 Å.

3. The method of claim 2, wherein the step of implanting phosphor as impurities so as to surround the region implanted with As is carried out by implanting phosphor with a concentration of 5×10¹³ atoms/cm² at a depth of about 600 Å.

4. The method of claim 1, wherein the distance between the gate electrode region and the capacitor region is smaller than 0.26 μm.

5. A method for manufacturing a semiconductor device, comprising the steps of:
defining gate electrode and capacitor regions by adapting a photoetching process to a semiconductor substrate deposited with a gate oxide film and a gate poly, so that the distance between the gate electrode region and the capacitor region can be smaller than twice the thickness of a spacer to be formed later;
growing an oxide film on top of the gate poly and defining a first LDD region using as impurities;
forming a spacer by depositing and etching an oxide film on the sidewalls of the gate oxide film and gate poly where the gate electrode and capacitor regions are defined; and
implanting a high concentration As one more time on the surfaces of a bit line contact junction and a gate poly formed between the gate electrodes by implanting a high concentration As to the surface of the resulting material with the spacer; and
wherein the method further comprises the step of forming a second LDD region so as to surround the first LDD region using phosphor (P) as impurities after carrying out the step of defining the first LDD region.

6. The method of claim 5, wherein the step of defining the second LDD region using phosphor is carried out by implanting the phosphor at a depth of 500 Å.

7. The method of claim 5, wherein the distance between the gate electrode region and the capacitor region is smaller than 0.26 μm.
